(19) United States
(12) Patent Application Publication
(10) Pub. No.: US 2009/0020150 A1
(43) Pub. Date: Jan. 22, 2009

(54) STRUCTURES OF ORDERED ARRAYS OF SEMICONDUCTORS

(76) Inventors: Harry A. ATWATER, South Pasadena, CA (US); Brendan M. KAYES, Los Angeles, CA (US); Nathan S. LEWIS, La Canada, CA (US); James R. MAIOLO, III, San Gabriel, CA (US); Joshua M. SPURGEON, Pasadena, CA (US)

Correspondence Address: Steinfl & Bruno, 301 N Lake Ave Ste 810, Pasadena, CA, 91101, US

(21) Appl. No.: 12/176,057

(22) Filed: Jul. 18, 2008

Related U.S. Application Data
(60) Provisional application No. 60/961,170, filed on Jul. 19, 2007.
(60) Provisional application No. 60/961,169, filed on Jul. 19, 2007.
(60) Provisional application No. 60/961,172, filed on Jul. 19, 2007.
(60) Provisional application No. 60/966,432, filed on Aug. 28, 2007.
(60) Provisional application No. 61/127,437, filed on May 13, 2008.

(51) Int. Cl. H01L 31/00

(52) U.S. Cl. 136/246; 257/E31.001

(57) ABSTRACT

A device having arrays of semiconductor structures with dimensions, ordering and orientations to provide for light absorption and charge carrier separation. The semiconductor structures are formed with relatively high aspect ratios, that is, the structures are long in the direction of received light, but have relatively small radii to facilitate efficient radial collection of carriers.

### CROSS-REFERENCE TO RELATED APPLICATIONS

The present application is related to and claims the benefit of the following copending and commonly assigned U.S. Patent Applications: U.S. Patent Application No. 60/961,170, titled “Fabrication of Wire Array Samples and Controls,” filed on Jul. 19, 2007; U.S. Patent Application No. 60/961,169, titled “Growth of Vertically Aligned Si Wire Arrays Over Large Areas (>1 cm²) with Au and Cu Catalysts,” filed on Jul. 19, 2007; U.S. Patent Application No. 60/961,172, titled “High Aspect Ratio Silicon Wire Array Photoelectrochemical Cells,” filed on Jul. 19, 2007; U.S. Patent Application No. 60/966,432, titled Polymer-embedded semiconductor rod arrays,” filed on Aug. 28, 2007 and U.S. Patent Application No. 61/127,437, titled “Regrowth of Silicon Rod Arrays,” filed on May 13, 2008, the entire contents of all of these applications are incorporated herein by reference.

The present application is also related to the following copending and commonly assigned United States patent applications: “Structures of and Methods for forming Vertically Aligned Si Wire Arrays,” Ser. No. ______ (Attorney Docket Number P226-US); “Polymer-embedded semiconductor rod arrays,” Ser. No. ______ (Attorney Docket Number P227-US); and “Method for Reuse of Wafers for Growth of Vertically-Aligned Wire Arrays,” Ser. No. ______ (Attorney Docket Number P260-US), filed on even date herewith and incorporated herein by reference in their entireties.

### STATEMENT REGARDING FEDERALLY SPONSORED RESEARCH OR DEVELOPMENT

The U.S. Government has certain rights in this invention pursuant to Grant No. DE-FG02-03ER15483 awarded by DOE.

### BACKGROUND

1. Field

This disclosure relates to structures for the conversion of light into energy. More specifically, the present disclosure describes devices for conversion of light to electricity using ordered arrays of semiconductor wires.

2. Description of Related Art

A key constraint in photon absorbers for solar energy conversion is that the material must be sufficiently thick to absorb most of the solar photons with energies above the material's band gap, yet sufficiently pure to have a high minority carrier diffusion length for effective collection of the photo generated charge carriers. This constraint imposes a cost floor on the absorber material by dictating the minimum required purity of the absorber phase. The situation is especially severe for indirect band gap absorbers, such as Si which requires over 100 μm of thickness to absorb 90% of the energy in sunlight above the 1.12 eV band gap of Si.

Inexpensive candidate materials for use in photovoltaic applications generally have either a high level of impurities or a high density of defects, resulting in low minority-carrier diffusion lengths. The use of such low diffusion-length materials as the absorbing base in a conventional planar p-n junction solar-cell geometry results in devices having a carrier collection limited by minority-carrier diffusion in the base region. Increasing the thickness of the base in such a cell will therefore produce more light absorption but will not result in an increase in device efficiency. In the absence of sophisticated light-trapping schemes, materials with low diffusion lengths and low absorption coefficients therefore cannot be readily incorporated into planar solar-cell structures with high energy-conversion efficiency.

Another approach for solar energy conversion is disclosed in Law, M.; Greene, L. E.; Johnson, J. C.; Saykally, R.; Yang, P. D. Nat. Mater. 2005, 4, 455-459. In Law, et al., an array of ZnO nanowires is coated with a dye and disposed in an electrolyte. The array of nanowires serves to increase the surface area exposed to solar radiation. The nanowires serve as support structures for the dye such that the primary absorber is the dye bound to the surface of the nanowires, not the nanowires themselves. Other wire array solar energy conversion devices may consist of randomly grown or randomly distributed wires that also have random orientations with respect to each other. Such wire arrays may have an appearance that may be characterized as similar to felt or felt-like.

### SUMMARY

The present disclosure describes a photo cell where vertically-aligned wire arrays are used for conversion of light energy to electrical energy. The wires in the wire arrays are preferably formed with relatively high aspect ratios. Such ratios provide for length in the direction of received light, but with relatively small radii to facilitate efficient collection of carriers. Different materials may be used to electrically contact the wires in the wire arrays. In a preferred embodiment, a liquid electrolyte is used in a photoelectrochemical cell. However, other embodiments may use other materials or means for contacting the wire arrays.

An embodiment of the present invention is a device comprising: a base conducting layer; an ordered array of elongate semiconductor structures, wherein the elongate semiconductor structures have length dimensions defined by adjacent ends in electrical contact with at least portions of the base conducting layer and distal ends not in contact with the base conducting layer and have radial dimensions generally normal to the length dimensions and the radial dimension are less than the length dimensions ; and a charge conducting layer, wherein at least some portions of the charge conducting layer are in electrical contact with one or more elongate semiconductor structures of the plurality of the elongate semiconductor structures along at least portions of the length dimensions of the one or more elongate semiconductor structures, where the elongate semiconductor structures absorb received light.

Another embodiment of the present invention is a photocell comprising: a substrate; one or more wire arrays comprising a plurality of oriented and ordered semiconductor wires, wherein the plurality of semiconductor wires have adjacent ends contiguous with the substrate and distal ends oriented to receive incident light, wherein the adjacent ends and distal ends define a length dimension for each semiconductor wire and wherein each semiconductor wire has a radius less than or equal to minority carrier diffusion lengths for material comprising the semiconductor wire; and a charge conducting layer, wherein at least some portions of the charge conducting layer are in electrical contact with the one or more semiconductor wires along at least portions of the length dimensions of the one or more semiconductor wires, where the semiconductor wires absorb received light and where a ratio of the length dimension to the radius for each semiconductor wire is optimal or near optimal for solar energy conversion for materials comprising the one or more semiconductor wires.

Still another embodiment is a photoelectrochemical cell comprising: a substrate; one or more wire arrays comprising a plurality of vertically-aligned semiconductor wires, wherein each semiconductor wire has an adjacent end contiguous with the substrate and a distal end oriented to receive incident light; a liquid electrolyte electrically contacting one or more semiconductor wires; and one or more electrical contacts to the substrate. The semiconductor wires may be formed by a vapor-liquid-solid growth process using a catalyst deposited on the substrate or other fabrication methods.

Still another embodiment is a photocell for conversion of water to hydrogen comprising: a photoanode comprising one or more ordered wire arrays comprising a plurality of elongate photoanode semiconductor wires, wherein the photoanode semiconductor wires are oriented to receive incident light; a photocathode comprising one or more ordered wire arrays comprising a plurality of elongate photocathode semiconductor wires, wherein the photocathode semiconductor wires are oriented to receive incident light; and a film electrically and ionically interconnecting the a plurality of the photoanode semiconductor wires to a plurality of the photocathode wires.

No limitation is intended by the description of exemplary embodiments briefly described above or those described in additional detail below.

### BRIEF DESCRIPTION OF THE SEVERAL VIEWS OF THE DRAWINGS

FIG. 1 is a schematic representation of a photoelectrochemical cell.

FIGS. 2A and 2B show scanning electron microscopy images of silicon wire arrays of grown Si wires.

FIG. 3 shows representative current density versus voltage curves from wire array samples using a liquid electrolyte.

FIG. 4 shows a test set-up used for collecting current density and voltage data.

FIGS. 5A-5I show a method for fabricating wire arrays.

FIG. 6 shows a tilted SEM view of a Cu-catalyzed Si wire array.

FIG. 7 shows representative tilted SEM images of regions near each of the four corners of a Cu-catalyzed Si wire array.

FIG. 8 shows an I-V measurement for an individually contacted nanowire using a four-point probe technique.

FIG. 9 shows a schematic representation of a photoelectrochemical cell.

FIGS. 10A-10F depict the fabrication of nanorods using an AAO membrane as a template.

FIG. 11 shows a cross-sectional SEM image of a Cd(Se, Te) nanorod array.

FIG. 12 displays a top-view SEM image of nanorod array electrodes.

FIG. 13 shows the J-E behavior for nanorod array electrodes.

FIG. 14 displays the J-E behavior of a nanorod array electrode cell before and after photoetching.

FIG. 15 shows the spectral response, before and after photoetching, of highest efficiency nanorod electrodes.

FIG. 16 depicts the spectral response data from a typical nanorod array electrode.

FIGS. 17A-17G show SEM images of pillars prepared by using an etch process.

### DETAILED DESCRIPTION

Within this description, the terms “wires,” “rods,” “whiskers,” and “pillars” and other similar terms may be used synonymously, except as otherwise indicated. Generally, these terms refer to elongate structures which have lengths and widths, where the length is defined by the longest axis of the structure and the width is defined by the axis generally normal to the longest axis of the structure. The term ‘aspect ratio’ refers to the ratio of a structure's length to its width. Hence, the aspect ratios of the elongate structures will greater than one. The terms “ball,” “spheroid,” “blob” and other similar terms may also be used synonymously, except as otherwise indicated. Generally, these terms refer to structures with the width defined by the longest axis of the structure and the length defined by the axis generally normal to the width. Hence, the aspect ratio of such structures will generally be unity or less than unity. Further the term “vertical” with reference to wires, rods, whiskers, pillars, etc., generally refers to structures that have a length direction that is elevated somewhat from horizontal. The term “vertical alignment” generally refers to an alignment or orientation of a structure or structures that is elevated from horizontal. The structure or structures do not have to be completely normal to horizontal to be considered to have a vertical alignment. The term “array” generally refers to multiple numbers of structures distributed within an area and spaced apart, unless otherwise indicated. Structures within an array all do not have to have the same orientation. The terms “vertically aligned array” or “vertically oriented array” generally refer to arrays of structures where the structures have orientations elevated from a horizontal orientation up to orientations completely normal to a horizontal orientation, but the structures within the array may or may not have all the same orientations with respect to horizontal. The terms “ordered” or “well-defined” generally refer to the placement of elements in a specified or predetermined pattern where the elements have distinct spatial relationships to one another. Hence, the terms “ordered array” or “well-defined” generally refer to structures distributed within an area with distinct, specified or predetermined spatial relationships to one another. For example, the spatial relationships within an ordered array may be such that the structures are spaced apart from one another by generally equal distances. Other ordered arrays may use varying, but specified or predetermined, spacings. The structures within “ordered” or “well-defined” arrays may also have similar orientations with respect to each other.

Within this description, the term “semiconductor” is generally used to refer to elements, structures, or devices, etc. comprising materials that have semiconductive properties, unless otherwise indicated. Such materials include, but are not limited to: elements from Group IV of the periodic table: materials including elements from Group IV of the period table; materials including elements from Group III and Group V of the periodic table; materials including elements from Group II and Group VI of the periodic table; materials including elements from Group I and Group VII of the periodic table; materials including elements from Group IV and Group VI of the periodic table; materials including elements from Group V and Group VI of the periodic table; and materials including elements from Group II and Group V of the periodic table. Other materials with semiconductive properties may include: layered semiconductors; metallic alloys; miscellaneous oxides; some organic materials, and some magnetic materials. The term “semiconductor structure” refers to a structure consisting of, at least in part, semiconductor material. A semiconductor structure may comprise either doped or undoped material.

Embodiments of the present invention comprise semiconductor structures with aspect ratios, ordering, density, and/or orientations with respect to incident light energy to increase absorption of light while providing for efficient radial collection of carriers. Preferably, the semiconductor structures orthogonalize the direction of light absorption with the direction of charge carrier collection. Therefore, the semiconductor structures have length dimensions generally in the direction of the incident light and width dimensions generally normal to the length dimensions. Light energy conversion devices according to embodiments of the present invention preferably have arrays of the semiconductor structures with a regular ordering to provide for increased numbers and increased density of structures for light energy reception. Electrical charge contacts to the semiconductor structures to conduct electrons from the semiconductor structures caused by carrier diffusion may be provided with a variety of approaches as discussed below.

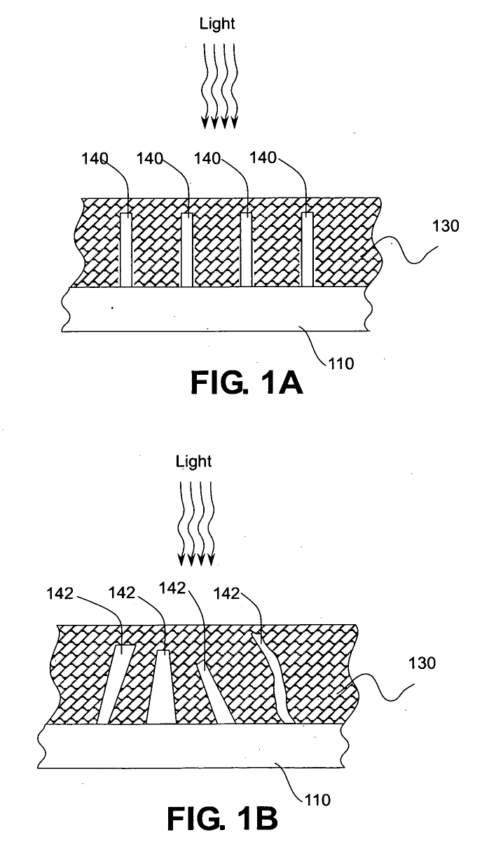

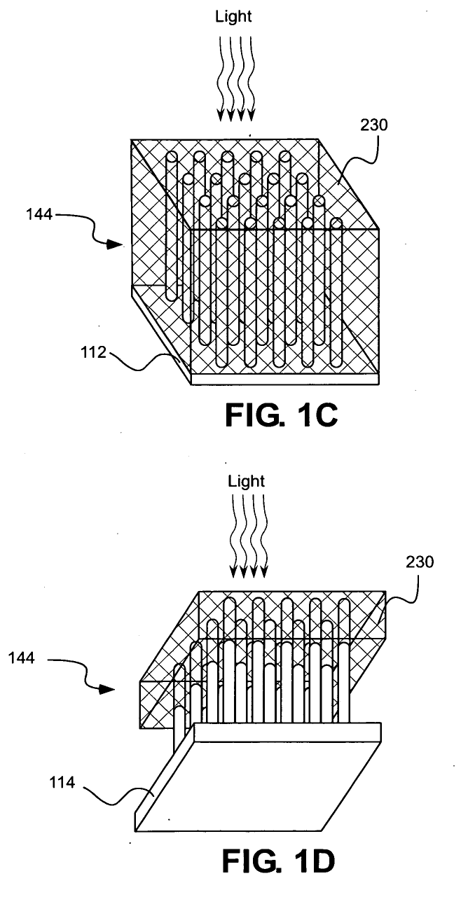

As shown in FIG. 1A, vertically aligned rods 140 of a rod array are positioned on a substrate 110. The rods 140 are disposed in charge conducting material 130. Preferably, the rods 140 in the rod array are formed with a relatively high aspect ratio and have radii roughly equal to minority carrier diffusion length. Hence, the rods 140 may provide for solar absorption along their entire length (depending upon the semiconductor material used for the rods) and, therefore, provide for carrier diffusion along the entire length. However, embodiments of the present invention are not limited to purely vertical orientations of identical rods. For example, FIG. 1B shows a light energy conversion device with an array of semiconductor structures 142 with a variety of shapes and orientation with respect to the substrate 110 and the direction of light. Note that in the embodiments depicted in FIGS. 1A and 1B, the substrate 110 may provide a base for the depicted semiconductor structures and/or provide electrical contacts to the semiconductor structures 140, 142.

In other embodiments according to the present invention, other approaches may be used for maintaining the ordering and orientation of the semiconductor structures without the use of a substrate. For example, see FIG. 1C, which shows semiconductor structures 144 contacting a base layer 112 and embedded within a binder layer 230. The binder layer 230 maintains the ordering and orientation of the semiconductor structures 144 so that they have a preferred orientation with respect to the reception of light. The base layer 112 provides electrical contacts to the semiconductor structures 144. The binder layer 230 may also provide for charge conduction from the semiconductor structures 144. The binder layer 230 may comprise, for example, a polymer material. FIG. 1D shows an embodiment where the semiconductor structures 144 are partially embedded in the binder layer 230 to provide the preferred orientation with respect to light reception. A conducting layer 114 provides electrical contacts to the semiconductor structures 144.

The semiconductor structures preferably comprise semiconductor material having properties for effective solar energy absorption and conversion of that energy to electricity. Such material may comprise crystalline silicon, either monocrystalline silicon or polycrystalline silicon, and doped or undoped. The semiconductor material may also be amorphous silicon, micromorphous silicon, protocrystalline silicon or nanocrystalline silicon. The semiconductor material may also be cadmium telluride; copper-indium selenide, copper indium gallium selenide gallium arsenide, gallium arsenide phosphide, cadmium selenide, indium phosphide, or a-Si:H alloy or combinations of other elements from groups I, III and VI in the periodic table; or other inorganic elements or combinations of elements known in the art for having desirable solar energy conversion properties, e.g., metallic oxide materials.

Charge conduction or electrical conduction from the semiconductor structures may be provided with a variety of materials. Charge conduction may provided by electrically conductive liquid electrolytes or other liquids. The electrolytes may be present in either aqueous or non-aqueous solvents. In other embodiments, charge conduction may be provided by conducting polymers. In still other embodiments, charge conduction may be provided by metals or other semiconductor structures electrically contacting the semiconductor structures in a manner to collect charge carriers. Essentially, anything that can conduct electrons may be used for the charge conduction material for embodiments of the present invention.

As indicated, embodiments of the present invention may comprise a photoelectrochemical cell using a non aqueous solvent solution containing a dissolved electrolyte and containing a redox couple dissolved in the solution which is suitable to accept and donate electrons from and to the semiconductor structures upon exposure of the cell by an external source of light. The non aqueous solvents may be of the type which self-dissociate into solvent molecules which are ionically conductive or may be a solvent such that an electrolyte added thereto will be substantially dissociated to form an ionically conductive solution. Exemplary classes of solvents comprise the alkanols of 1 to 10 carbon atoms, particularly methanol; nitriles of 2 to 10 carbon atoms, particularly acetonitrile; and a mixture of alkylene carbonate, such as propylene carbonate, with a minor amount of an alcohol. The alcohol in such a mixture may be a linear or branched, unsubstituted or halogenated alcohol of 1 to 10 carbon atoms. Exemplary alcohols include n-octanol, n-hexanol, n-butanol, trifluoroethanol, and methanol. Generally, the solvent will be a matter of choice within the ordinary skill of those in the art, utilizing conventional tables of solvent viscosities and dielectric constants. The electrolytes to be used may be determined from conventional tables of conductivities of ions in various solvents. For example, in methanol, the electrolyte may comprise lithium perchlorate because of its solubility. In acetonitrile, the electrolytes may comprise quaternary ammonium salts, particularly quaternary ammonium borontetrafluoride salts, such as tetraethyl ammonium borontetrafluoride. Exemplary redox couples are ferrocene-ferrocenium couples; however, other redox couples may be used. If the redox couple having an appropriate redox potential does not have the requisite solubility in the solvent of choice, then the redox couple may be chemically modified to impart greater solubility in the solvent. For example, the ferrocene molecule may be modified by introducing an alcohol side chain thereto according to conventional methods to make it more soluble in an alcohol solvent. In general, appropriate substituents may be introduced by known techniques to meet solubility requirements. Such substituents may include alkyl groups, carboxylic acids, esters, amides, alcohol groups, amino groups, substituted amino groups, sulfoxy groups, ketones, phosphate groups and the like. A preferred ferrocene ferrocenium couple is dimethylferrocene [O]/dimethylferrocenium [+] (DMFc/DFMc.⁺) with an appropriate anion, such as tetrafluoroborate. The use of other solvents, electrolytes, and/or redox couples in accordance with embodiments of the present invention would be apparent to those skilled in the art.

As indicated, embodiments of the present invention may also comprise photoelectrochemical cells using aqueous solvents with electrolytes. For example, the electrolyte may comprise 1 M Na₂S and 1 M S in an aqueous solvent of 1 M NaOH, maintained under an Ar ambient. The use of other aqueous solvents and corresponding electrolytes in accordance with embodiments of the present invention would be apparent to those skilled in the art.

As briefly described above, the charge conducting material in accordance with embodiments of the present invention is not limited to liquid materials. The charge conducting material may also comprise organic conductors, inorganic conductors, or mixed inorganic/organic conductors Organic conducting materials include (but are not limited to): conducting polymers (poly(anilines), poly(thiophenes), poly(pyrroles), poly(acetylenes), etc.)); carbonaceous materials (carbon blacks, graphite, coke, C₆₀, etc.); charge transfer complexes (tetramethylparaphenylenediamine-chloranile, alkali metal tetracyanoquinodimethane complexes, tetrathiofulvalene halide complexes, etc.); and other such materials. Inorganic conducting materials include (but are not limited to): metals and metal alloys (Ag, Au, Cu, Pt, Conductors AuCu alloy, etc.); highly doped semiconductors (Si, GaAs, InP, MoS₂, TiO₂, etc.); conductive metal oxides (In₂ O₃, SnO₂, Naₓ Pt₃ O₄, etc.); superconductors (YBa₂Cu₃O₇, Tl₂Ba₂Ca₂Cu₃O₁₀, etc.); and other such materials. Mixed inorganic/organic conductors include (but are not limited to): Tetracyanoplatinate complexes; Iridium halocarbonyl complexes; stacked macrocyclic complexes; and other such materials. As discussed above, just about any material that is capable of conducting electrons may be used for conducting charge from the semiconductors structures in accordance with embodiments of the present invention.

Having generally described embodiments of the present invention, the examples presented below provide additional detail on a few embodiments of the present invention. The first three examples may be categorized by the manner in which the semiconductor structures used in embodiments of the present invention are fabricated. The first example is of semiconductor structures grown from a substrate. The second example is of semiconductor structures deposited on a substrate. The third example is of semiconductor structures formed by etching a substrate. However, as discussed above, embodiments of the present invention may not have a substrate, so the examples below should not be considered as exhaustive of the manner in which the semiconductor structures may be formed. Embodiments of the present invention are not limited the production of electricity. The fourth example below describes a structure for the production of fuel, i.e., hydrogen, from arrays of semiconductor structures as described herein.

### EXAMPLE 1

### Photoelectrochemical Cell Comprising Grown Semiconductor Structures

As described in additional detail below, vertically-aligned wire arrays may be used for solar energy conversion where the wires in the arrays provide primary light absorption and charge carrier separation. Preferably, wires in the vertically-aligned wire arrays are formed with relatively high aspect ratios, that is, wires in the wire arrays are long in the direction of received light, but have relatively small radii to facilitate efficient radial collection of carriers. These radii can be small even for relatively impure absorber materials. Solar cell devices according to an embodiment of the present invention have relatively large area arrays of vertically aligned wires, means to make electrical junctions to such wire arrays and means to make electrical contacts to the backsides of these devices. In one embodiment, solar energy conversion is obtained by using wires as the primary light absorption and charge carrier separation material in contact with a liquid junction electrolyte.

FIG. 9 shows a schematic representation of a photoelectrochemical cell according to an embodiment of the present invention. As shown in FIG. 9, wires 940 of a wire array are positioned on a substrate 910. The wires 940 are disposed in an electrolyte 930. The substrate 910 preferably comprises a degenerately doped n-type Si(111) wafer. Preferably, the wires are grown from the substrate 910 in a manner as described in additional detail below to provide high aspect ratio crystalline Si wires. Preferably, the wires 940 in the wire array are formed with a relatively high aspect ratio. In one embodiment, wires 940 may be formed with length of 20-30 μm with diameters of 1.5-3 μm. In the photoelectrochemical cell, the wires 940 are oriented in a direction to receive incident light.

As described below, the Si wires 940 may be grown from the substrate using gold as a growth catalyst using a vapor-liquid-solid growth method. Although gold is a deep-level trap in silicon, the wires grown in the manner described below are nevertheless expected to allow effective carrier collection. Because the solubility limit of Au in Si at 1050° C. is ˜10¹⁶ cm⁻³, the trap cross-section of Au is expected to produce carrier lifetimes of 2 ns. This short lifetime would greatly restrict carrier collection in planar Si absorbers but, nevertheless, is adequate to provide carrier collection for distances of at least 1 μm. Optimal efficiencies are expected when each wire has a radius comparable to the minority carrier diffusion length. Smaller radii produce increased surface area and thus increase surface and junction recombination with little concomitant improvements in carrier collection. Hence, embodiments of the present invention may use micron-diameter Si wires.

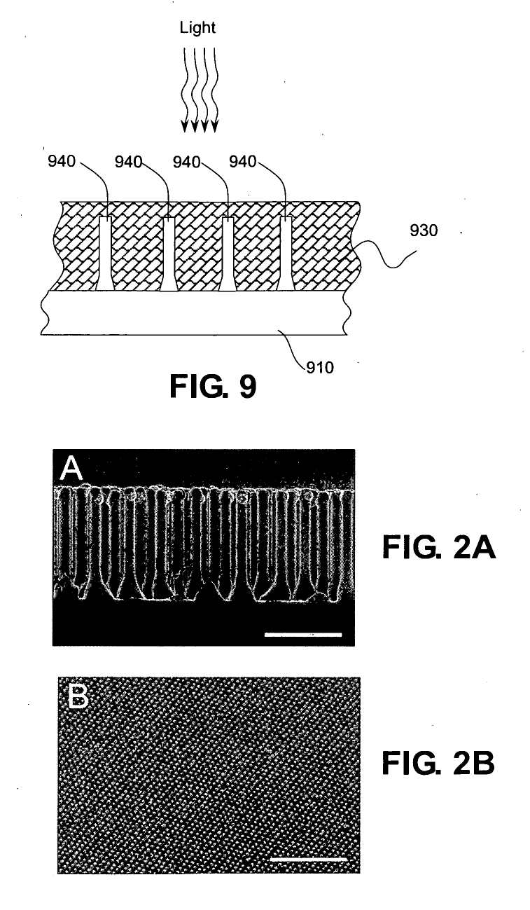

FIGS. 2A and 2B show scanning electron microscopy images of silicon wire arrays of the grown Si wires used in some embodiments of the present invention. FIG. 2A shows a cross section, where the scale bar is 15 μm and FIG. 2B shows a 45° view, where the scale bar is 85.7 μm. As shown in FIGS. 2A and 2B, the grown Si wires are nearly completely oriented normal to the substrate and are highly regular, in both diameter and pitch, over a large (˜2 mm²) area.

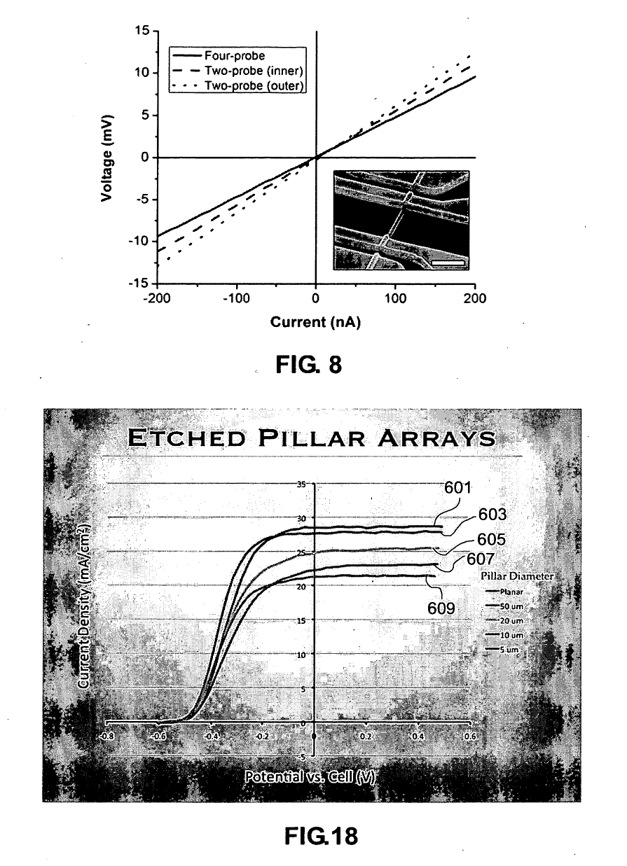

To characterize the electrical properties of the grown Si wires, four-point probe and field-effect measurements were performed on individual wires in the arrays. Back-gated measurements indicated that the as-grown wires were n type, with resistivities of 0.32 Ω·cm, corresponding to dopant densities of 2.9×10¹⁶ cm⁻³, assuming that the carrier mobility in these wires is the same as that in bulk Si. FIG. 8 shows an I-V measurement for an individually contacted nanowire using the four-point probe technique. The inset in FIG. 8 is a SEM image of the four-probe measurement device, viewed at 45°. The scale bar is 6 μm.

As indicated, an embodiment of the present invention comprises a photoelectrochemical cell, where the cell utilizes a liquid electrolyte. Therefore, the junction properties of grown Si wire arrays were probed using a liquid electrolyte. The liquid electrolyte provides a convenient, conformal method of contacting the Si wires and allows measurements of the performance of the wires without requiring a diffused metallurgical junction to the Si wires in the array. However, other embodiments of the present invention may use such junctions.

In one embodiment, a liquid electrolyte comprising the 1,1′-dimethylferrocene (Me₂Fc)^{+/0} redox system in CH₃OH is used. Such an electrolyte may yield excellent junctions with n-type Si, providing bulk diffusion-recombination-limited photovoltages in excess of 670 mV under 100 mW cm⁻² of AirMass (AM) 1.5 conditions. Such junctions also form an in situ inversion layer in the n-Si, in essence forming an in situ p+emitter layer, while also producing a highly passivated surface. Hence these liquid junctions are well suited as systems for providing initial probes of the solar device conversion properties of arrays of n-type Si wires.

Experiments were performed to compare the performance of samples with V-L-S grown Si wire arrays with control samples. To generate control samples, an oxidized substrate wafer was patterned with holes, but no catalyst was deposited into the openings and wires were not grown on the samples. Measurements were made of the open-circuit voltage (V_{oc}) and the short-circuit density (J_{sc}) of samples with the grown Si wires and the control samples. The samples with the grown Si wire arrays provided V_{oc}(mV)=389±18 and J_{sc}(mA/cm²)=1.43±0.14, while the control samples provided only V_{oc}(mV)=232±8 and J_{sc}(mA/cm²)=0.28±0.01. The V_{oc} in the wire array samples was relatively large (350-400 mV) given the high surface area per unit projected area. This value of V_{oc} reflects the relatively low surface recombination velocity of the Si/Me₂Fc^{+/0}—CH₃OH interface and good bulk properties of the Si wires, without which much lower V_{oc} values would be observed. The short-circuit photocurrent densities of the wire array samples were relatively low, 1-2 mA cm⁻². However, on this experiment, the wires were only 20 μm in length, so the expected J_{sc} of 43 mA/cm⁻² that could be attained for complete absorption and collection of all solar photons with energies above the 1.12 eV band gap of Si is reduced to 34 mA cm⁻² for a 20 μm thickness of Si absorber. In addition, the array of 2 μm diameter wires on a 7 μm pitch only fills 6.5% of the projected surface plane, thereby producing an expected maximum Jsc of 2.2 mA/cm⁻², in agreement with the observed J_{sc}.

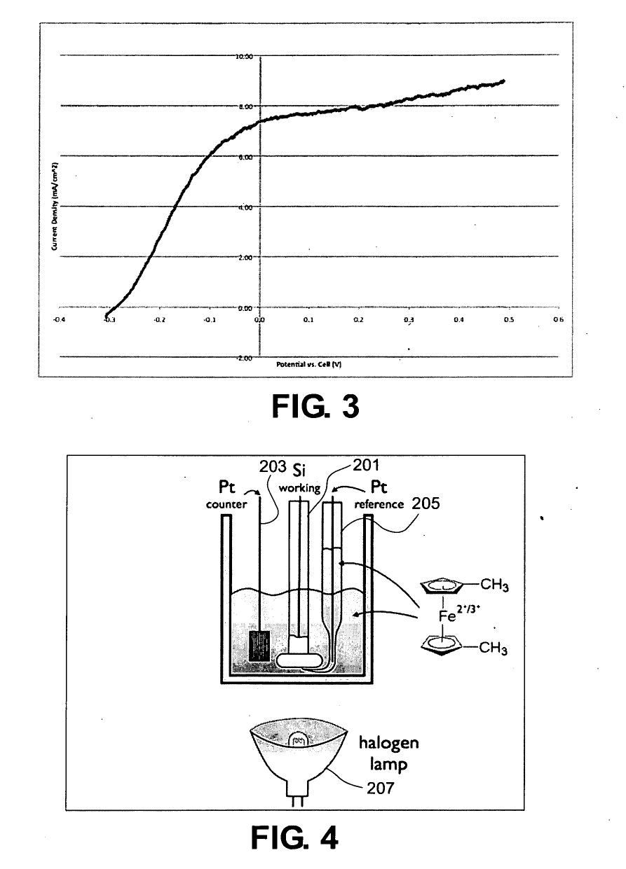

FIG. 3 shows representative current density versus voltage curves from the experiment. In the experiment, the open circuit voltage was around 330 mV, the short circuit current density was around 6.8 mA/cm², and the fill factor was about 0.31, giving an efficiency of about 0.7%. The observed photoactivity was not dominated by the substrate because the degenerately doped substrate produced only a low photovoltage and nearly no photocurrent. In addition, the wide bases of the wires suggest that relatively little, if any, direct contact was formed between any remaining oxide-free substrate and the liquid electrolyte. Thus, it is likely that all of the observed photocurrent and photovoltage was due to the wires rather than the substrate.

FIG. 4 shows the test set-up used for the experiments described immediately above. Prior to performing the test, samples with the grown wire arrays were dipped in 1 M HCl (aq) and rinsed with H₂O. The samples were then etched for 10 s in 10% HF (aq) to remove native oxide, rinsed with H₂O, and dried under a stream of N₂. Ga/In was immediately rubbed onto the back of each sample, and the samples were attached to a wire coil using silver paint. The samples were then sealed inside a glass tube, leaving ˜2 mm² of exposed front surface area, using 20-3004 LV epoxy (Epoxies, Etc.) to coat the front face and sealing the rest of the sample with Hysol 1C epoxy (Loctite). The control samples consisting of oxidized wafers that contained patterned openings in the oxide, but with no deposited catalyst and no grown wires, were similarly prepared.

The photoelectrochemical measurements were performed in a solution consisting of 200 mM of dimethylferrocene (Me₂Fc), 0.5 mM of Me₂FcBF₄, and 1 M of LiClO₄ in methanol. Methanol was clearly observed to wet the wire array surfaces during both processing and photoelectrochemical measurements. As shown in FIG. 4 the working electrode 201 was either a wire array sample or a control sample. The counter electrode 203 was a Pt mesh, and the reference electrode 205 was a Pt wire enclosed in a Luggin capillary that contained the same solution as the main cell. All cell components were assembled under an inert atmosphere and were sealed before being placed under positive pressure of Ar. During measurements, the cell was illuminated using a 300 W ELH-type projector bulb 207. The light intensity was calibrated using a Si photodiode to produce a photocurrent equivalent to that obtained under 100 mW cm⁻² of AM1.5 illumination at the working electrode surface. The solution was stirred vigorously during measurement, and a stream of air was used to keep the cell temperature constant under illumination.

Photoelectrochemical measurements were conducted using a Solartron 1287 potentiostat and the CoreWare software. To measure the open-circuit voltage in the light, the open-circuit potential was first allowed to equilibrate in the dark (always to within 10 mV of 0 V). The light was then switched on and the sample was allowed to equilibrate in the light. The reported V_{oc} is the difference between the potential in the dark and the potential in the light. J-V data were then recorded in the light at a scan rate of 10 mV s⁻¹. The short-circuit photocurrent densities were recorded as the current density measured at a bias of 0 V vs the Nernstian potential of the cell. The electrode area used to calculate the current density was measured using a flatbed scanner.

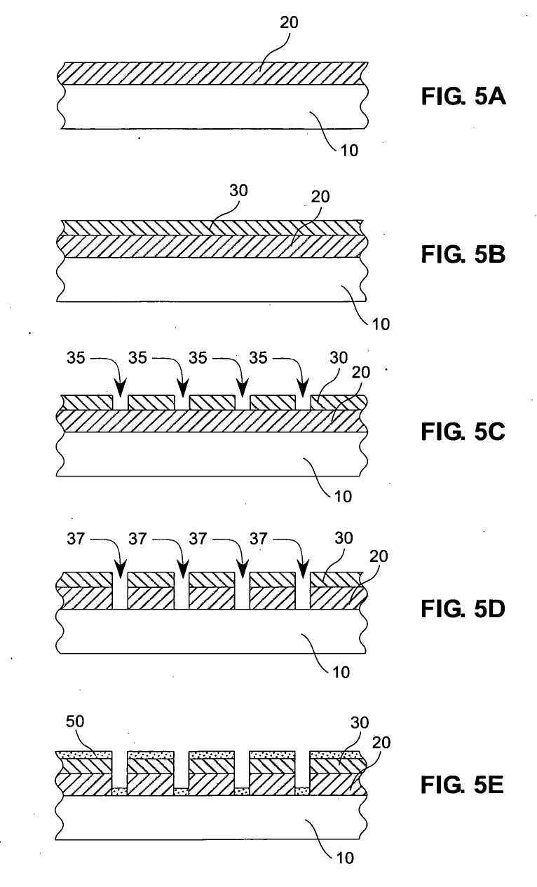

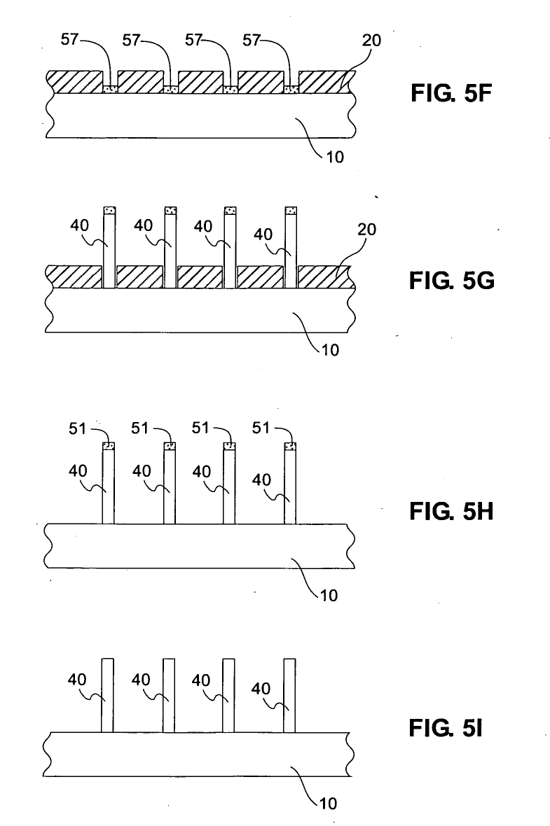

A method for forming vertically aligned Si wire arrays is now described. An Si <111> wafer may be used as the material from which the wire arrays are grown. Other materials may also be used to support wire growth, such as a thin Si layer disposed on glass, or other such Si substrates. All or portions of the wafer may be doped. For example, a degenerately doped n-type Si wafer may be used. As shown in FIG. 5A, a surface oxide layer 20 is thermally gown on the wafer 10. In one embodiment, the surface oxide layer is grown to a thickness of 285 nm. In another embodiment, the surface oxide layer 20 is grown to a thickness of 300 nm. Other embodiments may comprise oxide layers at other thicknesses. Still other embodiments have the oxide layer 20 deposited via chemical vapor deposition (CVD) or other methods known in the art.

As shown in FIG. 5B, a photoresist layer 30 is applied. The photoresist layer is applied to support the development of a patterned template as discussed below. However, other materials and techniques for creating a patterned template may be used, such as a latex layer, or stamping or soft lithography. The photoresist layer may comprise S1813 photoresist from MicroChem Corp. (Newton, Mass., USA) or other photoresist material. The photoresist layer 30 is then exposed to a desired array pattern and developed with a developer to form a desired pattern of holes 35 in the resist layer 30 as shown in FIG. 5C. The developer may comprise MF-319 or other developers known in the art. The patterned resist layer 30 is then used to etch the oxide layer 20 on the Si wafer 10 as shown in FIG. 5D. Etching of the oxide layer may be achieved by using hydrofluoric acid compositions such as buffered HF (9% HF, 32% NH₄F) from Transene Company, Inc. (Danvers, Mass., USA). Other etching techniques known in the art may also be used to etch the oxide layer 20. The result of the etching will be a pattern of holes 37 in the oxide layer as shown in FIG. 5D. A preferred pattern of holes may be a square array of 3 μm diameter holes that are 7 μm center to center.

A growth catalyst 50 is then thermally evaporated onto the resist layer 30 and into the holes 37 in the oxide layer 20 as shown in FIG. 5E. Other methods of depositing the catalyst may be used, such as electrodeposition. Preferred catalysts comprise gold, copper, or nickel, but other catalysts known in the art for promoting growth as described herein may be used. For example, 500 nm of gold may be thermally evaporated onto the resist layer 30 and into the holes 37. Lift-off of the photoresist layer 30 is then performed, leaving catalyst islands 57 separated by the oxide in the oxide layer 20 as shown in FIG. 5F.

The wafer 10 with the patterned oxide layer 20 and the deposited catalyst may then be annealed. Preferably, the annealing is performed in a tube furnace at a temperature between 900 to 1000° C. or at a temperature of about 1050° C. for 20 minutes with the application of 1 atm of H₂ at a flow rate of 1000 sccm (where SCCM denotes cubic centimeters per minute at STP). Growth of wires on the wafer 10 is then performed. FIG. 5G shows the growth of wires 40 in a wire array through the application of a growth gas. Preferably, the wires 40 are grown in a mixture of H₂ (1000 sccm) and SiCl₄ (20 sccm) at about 1 atm. The wires 40 may be grown for between 20 to 30 minutes at temperatures between 950° C. to 1100° C. or with different growth times, pressures, and or flow rates. However, optimal growth temperatures are between 1000° C. and 1050° C. Growth for these times and at these temperatures may produce wires from 10 μm to 30 μm in length or longer.

Following the growth of the wires 40, the oxide layer 20 may be removed, as shown in FIG. 5H. The oxide layer 20 may be removed by etching the wafer 10 for 10 seconds in 10% HF (aq) or other methods known in the art may be used to remove the oxide layer. As shown in FIG. 5H, catalyst particles 51 may remain at the top of each grown wire 40, which may impact the functionality of the resulting wire array. Therefore, it may be advantageous to remove the catalyst particles. For example, if the catalyst comprises Au, the gold particles may be removed by soaking the wafer 10 for 10 min in a TFA solution from Transene Company, Inc., which contains I⁻/I₃⁻. Other methods known in the art may also be used to remove catalyst particles. FIG. 5I shows the wires 40 with the catalyst particles 51 removed.

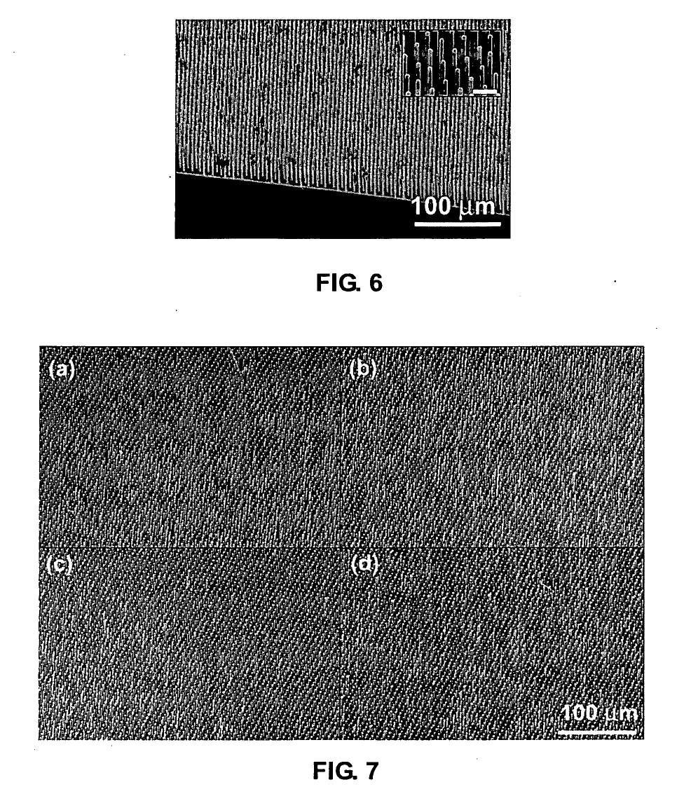

As discussed above, other catalysts may be used to facilitate the growth of the Si wires in the wire array. Nominally identical wire arrays may be obtained when Cu is used as the VLS catalyst instead of Au. FIG. 6 shows a tilted SEM view of a Cu-catalyzed Si wire array produced using the method described above where the array has nearly 100% fidelity over a large >1 cm² area. The scale bar in the inset in FIG. 6 is 10 μm. FIG. 7 shows representative tilted SEM images of regions near each of the four corners of a 0.5×1 cm sample grown at 1000° C. with Cu catalyst, illustrating the uniformity over large areas. The scale bar in FIG. 5 applies to all panels.

Cost motivates the use of non-Au catalysts for growing wire arrays using V-L-S techniques. As indicated above, Cu may be used as a catalyst for Si wire growth. Cu is, unlike Au, an inexpensive, earth-abundant material, and, therefore, of particular interest for such embodiments. Although Cu is more soluble in Si than Au and is also a deep trap, Si solar cells may be more tolerant of Cu contamination than of Au, and thus diffusion lengths of at least microns even in the case of Cu catalyzed growth can be expected.

Other methods may be used for growing vertically-aligned wire arrays, so embodiments of the present invention are not to be limited to creation by the method described above. For example, other catalysts than the ones described may be used. Other methods may use other techniques for patterning the surface oxide. Still other methods may not use a thermally grown oxide to support wire growth. Wire growth (or growth of other semiconductor structures as discussed below) may be complished with templating layer that is first patterned with openings (e.g., an array of holes) holes in which the wires or structures are to be grown. The templating layer comprises a diffusion barrier for the deposited catalyst. The diffusion barrier may comprise a patterned oxide layer, an patterned insulating layer, such as a layer comprising silicon nitride, a patterned metal layer, or combinations of these materials or other materials or processes that facilitate the deposition of the catalyst for semiconductor structure growth

As described above, vertically aligned arrays of high aspect ratio silicon wires may be fabricated over relatively large areas. The result is that a nearly photoinactive substrate may be rendered photoactive by the scalable, relatively low-cost, VLS growth of arrays of wires. In an embodiment as described in additional detail above, such wire arrays may be used in a photoelectrochemical cell using a liquid electrolyte. Given the photoactive properties of the gown Si wire arrays, other embodiments may provide desired photoactive properties without the use of a liquid electrolyte to contact the wire arrays. For example, contact to the wire arrays may be a liquid, a conducting polymer, a PN junction, a metal oxide semiconductor interface, or any combinations there of or others. Further, while Si wire arrays are described above, other semiconductor material may be used for the formation of wire arrays. In particular, embodiments of the present invention preferably comprise wire arrays where the individual wires have radii and/or aspect ratios that are optimal or near optimal for solar conversion based on the material used for the wire arrays.

In accordance with embodiments of the present invention, semiconductor structures other than wire arrays may be grown on the substrate. This other semiconductor structures may include, but are not limited to, pyramids, trees, etc. Further, embodiments of the present invention are not limited to semiconductor structures grown using the V-L-S procedure and oxide layer described above, but may also include other growth techniques, such as growth using a template or spontaneous growth.

### EXAMPLE 2

### Photoelectrochemical Cell Comprising Deposited Semiconductor Structures

Another embodiment of the present invention comprises a photoelectrochemical cell having radial rod array junction photoelectrodes prepared by electrodeposition of Cd(Se, Te) and is described below. The II-VI semiconductors CdSe and CdTe are both direct gap, highly absorbing materials having band gaps (1.7 eV for CdSe and 1.4 eV for CdTe) well-matched to the solar spectrum. The materials can both be deposited by a number of techniques. Electrodeposition of CdTe and CdSe is well established, and the photovoltaic or photoelectrochemical cell performance of the electrodeposited forms of these materials are usually limited by low minority-carrier collection diffusion lengths in the absorber phase.

Embodiments of the present invention may use several methods for the fabrication of entire arrays of vertically aligned semiconductor nanorods. When a deposition technique that does not induce one-dimensional growth is used, production of a nanorod array may require the use of a template. Anodic aluminum oxide (AAO) templates may be used to facilitate the electrodeposition of arrays of II-VI semiconductor nanorods. The pores of AAO are dense, relatively uniform in dimension, and highly vertically aligned. These pores can be fabricated with controllable pore aspect ratios, with pore diameters ranging from 5 nm to 200 nm, and with densities as high as 10¹¹ pores cm⁻². AAO templates can be formed by anodization of Al under a bias of 10-100 V in an acidic solution of sulfuric acid, phosphoric acid, or oxalic acid, or are commercially available. AAO membranes are particularly compatible with electrodeposition methods because the insulating properties of the alumina prevent material from depositing directly onto the template. After fabrication of the rods, the template can be selectively removed in an aqueous solution of sodium hydroxide, leaving behind a free-standing, vertically aligned nanorod array.

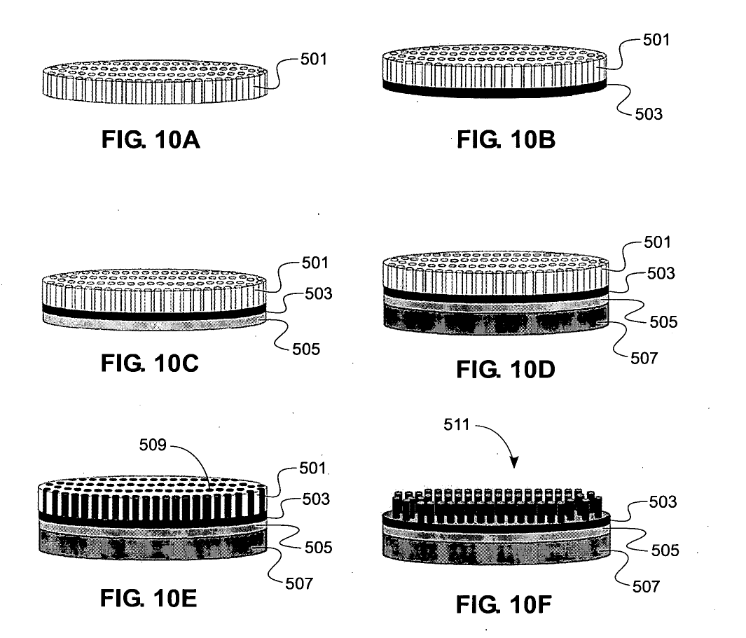

FIGS. 10A-10F depict the fabrication of nanorods using an AAO membrane as a template. FIG. 10A depicts an AAO membrane 501. Nanorod array electrodes may be fabricated using commercially available, 60 μm thick, 200 nm pore diameter, AAO membranes (Whatman Scientific) as templates. FIG. 10B depicts the sputtering of a thin CdSe film 503 on one side of the template 501. The thin CdSe film 503 may comprise a 300 nm thick layer of CdSe 503 (deposited using a RF magnetron sputterer, CdSe sputter target of 99.995% purity, Kurt J. Lesker Company) deposited onto one side of the AAO template 501 to cover the bottoms of the pores. FIG. 10C depicts the sputtering of a Ti ohmic back contact layer 505 onto the back of the CdSe layer 503. The Ti ohmic back contact layer 505 may be fabricated by sputtering 1.5 μm of Ti (99.995% purity Ti sputter target, Kurt J. Lesker Company) onto the back of the CdSe layer 503. The other side of the AAO template 501 was then covered in a layer of mounting wax (not shown), to prevent deposition of metal, in subsequent steps, onto the bottoms of the pores. The template was then made into a working electrode by attaching a Cu wire and applying conductive Ag paint around the edge of the membrane. The wire was encased in a glass tube, and the wire contact area was sealed with epoxy.

To provide mechanical stability and support for the nanorod array after the removal of the template, >10 μm of Ni metal was then electrodeposited onto the back of the Ti. FIG. 10D depicts the deposition of the Ni metal substrate 507 onto the Ti layer 505. The Ni substrate 507 was galvanostatically electrodeposited at room temperature, under stirring, from an aqueous solution of 0.8 M nickel (II) sulfamate (Ni(SO₃NH₂)₂) and 0.6 M boric acid (H₃BO₃). In this process, a current density of 25 mA cm⁻² was maintained for 1 hr between the working electrode and a Pt gauze counterelectrode. The mounting wax was then thoroughly removed by several washes in acetone. CdSe_{0.65}Te_{0.35} was then electrodeposited into the pores using an aqueous deposition bath that contained 0.2 M CdSO₄, 20 mM SeO₂, and 10 mM TeO₂ in 1 M H₂SO₄. FIG. 10E shows the deposition of the CdSeTe 509 into the pores of the AAO template 501. Triton X-100 was also added (0.25%) to reduce the surface tension and to improve the quality of the deposit. In addition to the Pt gauze counter, a saturated calomel electrode (SCE) reference was used with the AAO working electrode. The electrodeposition was performed potentiostatically at −650 mV versus SCE, at room temperature, without stirring, for 5 to 30 min.

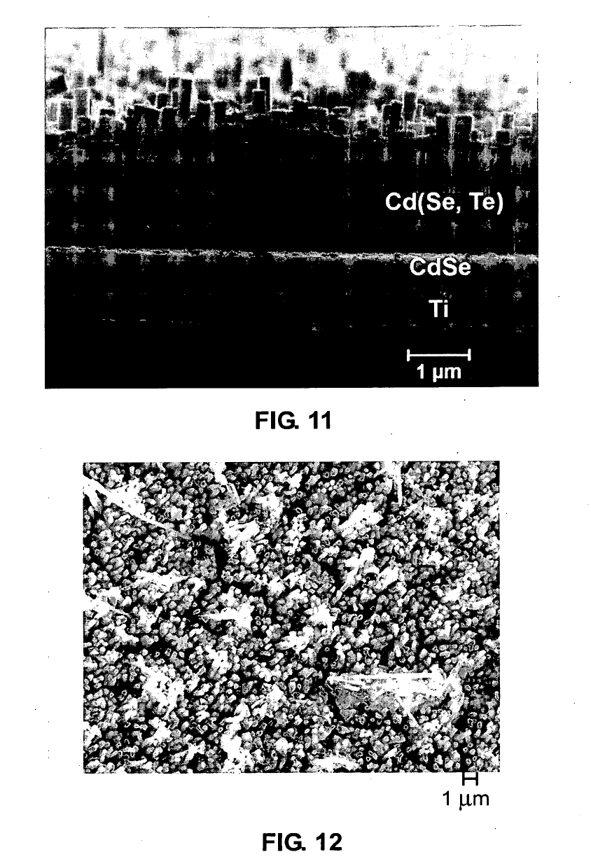

After growth of the nanorods, the AAO template 501 was removed by submersion of the electrode assembly for 20 min into 1 M NaOH_{(aq)}. FIG. 10F shows the nanorods 511 remaining after the removal of the template 501. The nanorod array was then thoroughly rinsed in 18 MΩ cm resistivity H₂O, dried, and detached from the Cu wire. The array was then annealed for 90 min at 600° C. in an Ar atmosphere that contained a small percentage (˜0.2%) of O₂. The nanorod array was then cut into smaller samples (0.1-0.3 cm²), and the samples were made into electrodes for use in photoelectrochemical cell measurements. FIG. 11 shows a cross-sectional SEM image of a Cd(Se, Te) nanorod array after the removal of the AAO template. The contrast in the substrate indicates the transition from the Ti ohmic back contact to the sputtered CdSe shunt-preventing layer. The Ni supporting layer is not visible in this image because when the electrode was cut, the Ni separated from the Ti at the edges of the sample. EDS indicated that the elemental composition was Cd:Se:Te in the ratio 3:2:1, to within a few percent. FIG. 12 displays a top-view SEM image of the nanorod array electrodes.

The nanorod assembly fabricated as discussed above was then used in a photoelectrochemical assembly. The photoelectrochemical assembly consisted of the working electrode, a Pt gauze counterelectrode, a Pt wire reference, and a liquid electrolyte, all in a glass cell (see also FIG. 4). The electrolyte was 1 M Na₂S and 1 M S in aqueous 1 M NaOH, maintained under an Ar ambient. The cell potential determined at the Pt reference electrode was −0.72 V vs. SCE, which corresponds to the redox potential of the solution species and is in agreement with the literature value of the Nernst potential for this electrolyte.⁴³ The electrolyte was deoxygenated when made, and was kept under a positive pressure of Ar through the use of a Schlenk line. To prevent evaporation of the solution, the Ar was saturated with water vapor by bubbling the gas flow through 18 MΩ cm resistivity H₂O prior to introduction of the gas into the cell.

Current density vs. potential (J-E) data were measured using a Solartron SI 1287 potentiostat. Light from a Sylvania ELH-type halogen projector bulb was passed through a ground-glass diffuser to provide the equivalent of 100 mW cm⁻², as measured using a Si photodiode that had been calibrated relative to a secondary standard, NIST traceable, Si photocell calibrated at 100 mW cm⁻² of Air Mass (AM) 1.0 illumination. Before collection of J-E data, each electrode was allowed to reach equilibrium at open-circuit. J-E data were then measured on each electrode before and after a photoetch step. Photoetching was performed by immersing the electrode in a 90:9.7:0.3 H₂O:HCl:HNO₃ (v/v) solution for 10 s at short-circuit, under 100 mW cm⁻² of ELH-type illumination.

Nanorod array electrodes were fabricated by electrodeposition of Cd(Se, Te) for times ranging from 5 min to 30 min. Those arrays that were measured to have the best performance under illumination had deposition times of 20 min, which corresponded to a total charge passed of 2-2.5 C cm⁻² of template area. SEM images (see FIG. 11) revealed that the nanorods in these arrays varied in length from ˜3.5-7.0 μm. In any particular array, however, the rods were within 1 μm of each other in length. These nanorod electrodes were also tested before and after the photoetching process.

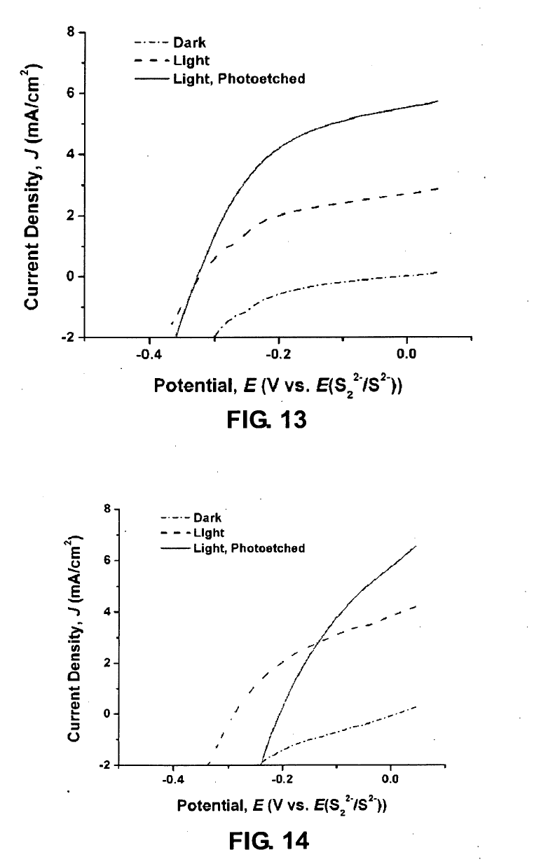

FIG. 13 shows the J-E behavior for better performing nanorod array electrodes. In many cases and as shown in FIG. 13, the photoetching step significantly improved the efficiency of the nanorod array electrodes. Photoetching of the nanorod arrays always increased J_{sc}, but only sometimes improved V_{oc}. For the majority of the nanorod electrodes, in fact, the photoetch step significantly reduced V_{oc}. FIG. 14 displays the J-E behavior of one such cell before and after photoetching.

Control experiments were performed to evaluate the effect of the sputtered CdSe layer on the performance of the nanorod array electrodes. In these experiments, every step in the fabrication process of a nanorod array was followed, except for the deposition of Cd(Se, Te) into the pores of the template. The resulting electrode thus just consisted of a thin layer of annealed CdSe on a Ti/Ni substrate. This electrode had a very low efficiency, of 0.11% before photoetching and 0.03% afterwards.

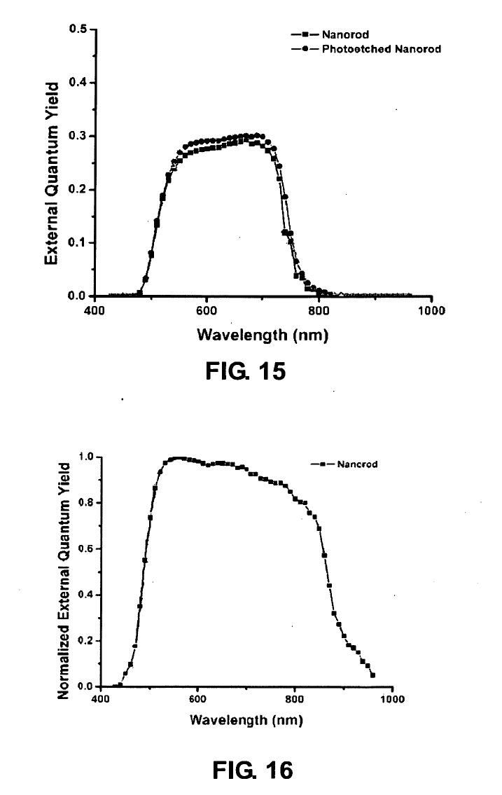

FIG. 15 shows the spectral response, before and after photoetching, of the highest efficiency nanorod electrodes produced as described above. Absorbance spectra taken on the polysulfide liquid electrolyte confirmed that the solution was highly absorbing at wavelengths, λ, <500 nm, accounting for the decline in external quantum yield of the Cd(Se Te) photoelectrodes at short wavelengths. The high absorbance in this region also implies that slight differences in the path length of the light through the solution have a strong effect on the external quantum yield for λ<500 nm, likely accounting for the difference in this region between the spectral response observed for the nanorod. As shown in FIG. 15, the external quantum yield of the nanorod array electrode stayed relatively constant until the onset of the band gap. FIG. 16 depicts the spectral response data from a typical nanorod array electrode. The data in FIG. 16 have each been normalized to their respective points of highest quantum yield, so that the shapes of the spectral response data can be readily compared. The nanorod array electrodes exhibited less of a decline in quantum yield near the band gap, indicating that such nanorod array samples effectively collected minority-carriers generated from photons having longer penetration depths.

The nanorod array electrodes fabricated in the experiment did, however, typically exhibit lower overall short-circuit current densities than what might be seen for planar electrodes. This likely reflects the lack of a complete filling fraction of the incident optical plane of the specific nanorod electrode arrays used in this work. Therefore, alternative embodiments use other methods to prepare higher density nanorod arrays, with less void area between the rods. Optical scattering may also partly mitigate the lack of a high optical filling fraction of the nanorod arrays, and photon management schemes may be used to great advantage in such systems. Also note that the nanorod array electrodes were jet black. Hence, to some extent, light trapping is already occurring in such systems, but possibly not with sufficient magnitude to produce the highest quantum yields that are possible from such systems.

The nanorod array electrodes fabricated as described above generally yielded open-circuit voltage values, V_{oc}, smaller than that which would be obtained from typical planar electrodes. The decline in V_{oc} may be related to two factors, one inherent to the nanorod array geometry, and one that can be manipulated, in principle, with optimized materials processing and junction formation. The inherent effect is that the nanorod array electrodes distribute the photogenerated minority-carrier flux over a larger junction collection area than is present for a planar electrode geometry. Specifically, the ratio of the junction area for a nanorod array electrode to a planar electrode is:

λ=A_{NR}/A_{P}=(2πrhρ_{NR}LW)/(LW)=2πrhρ_{NR}

where A_{NR} is the area of the nanorod array electrode junction, A_{P} is the area of the planar electrode junction, r is the radius of a single nanorod, h is the height of the nanorods, ρ_{NR} is the density of nanorods (number of rods per unit of planar base area), and L and Ware the length and width of the planar projected area, respectively. Note that this definition of γ implicitly assumes that the nanorod array junction area consists only of the rod sidewalls and neglects the area at the top of the rods as well as at the base between rods. For the arrays fabricated as described above, r˜100 nm, ρ_{NR}˜10⁹ nanorods cm⁻², and h varied from 3.5-7.0 μm. For a nearly optimum absorber thickness, i.e., with h=n(1/α), with n˜2-3 where α is the absorption coefficient, γ˜19 for the same radius and density rods. For the specific samples used herein, γ˜22-44. Hence, if the rate of production of photogenerated charge carriers is the same for both samples, then the minority-carrier flux across the junction boundary will be less for each nanorod in the nanorod array electrode than is present across the same projected area for the planar junction system.

Because the open-circuit voltage is related to the photocurrent density across the junction area by the relationship:

V_{oc}=(kT/q)ln(J_{sc}/γ Jₒ)

where k is the Boltzmann constant, T is the temperature, q is the elementary charge, Jₒ is the reverse saturation current density over the actual junction area, and J_{sc} is the short-circuit current density per unit of projected device area, V_{oc} will be decreased in nanorod electrode array samples having γ>>1 relative to the value of V_{oc} produced by an analogous absorber and junction in a planar electrode arrangement. Note that for γ>>1 this inherent geometry effect may tend to bias the optimum design away from the smallest nanorod diameters, due to the resultant increased junction area of such systems. In the present case, the increased junction area per unit of projected area is a factor of approximately 30, which will produce a decrease in V_{oc} of 90 mV for the nanorod array electrode relative to a planar electrode if all other parameters are equivalent. However, since the J_{sc} of the nanorod array electrodes were lower than those of planar electrodes, the equation above demonstrates that they will have an even lower V_{oc} as a result.

Surface and/or junction recombination can also lower V_{oc} in nanorod array electrodes. The V_{oc} for junctions between the Cd(Se, Te) electrodes and the S₂²⁻/S²⁻ electrolyte is lower than the bulk recombination-diffusion limit, which is approximately 1.0 V under AM 1.0 100 mW cm⁻² conditions according to the Shockley diode equation. This value is significantly higher than the observed V_{oc} of the nanorod array junction systems, which may indicate that the limiting process at present is related to a recombination process associated with the solid/liquid junction. Hence, improved junction fabrication methods that lower the Jₒ of the solid/liquid contact are expected to produce an increase in V_{oc} for such systems, up to the value of the theoretical limit obtained from the Shockley diode where Jₒ has incorporated into it the junction-area-corrected relationship of the equation above.

Experimental evidence that V_{oc} in these specific nanorod array systems may be limited by junction-derived recombination is also provided by consideration of the effects of photoetching. The improvement in photoelectrode performance due to photoetching may derive from a reduction in the reflectivity of planar electrode samples by the photocorrosion of small pits in the surface. However, the nanorod array electrodes appear black and should inherently produce significant internal light scattering and light trapping. Nevertheless, photoetching improved the J_{sc} and external quantum yields of planar and nanorod array samples. In addition, photoetching improved the V_{oc} of some nanorod array electrodes but reduced the V_{oc} of the majority of the nanorod array electrodes. If photoetching occurs due to photocorrosion, and therefore produces a roughening of the surface, surface recombination should then be increased due to the increased value of the junction surface area, thereby decreasing V_{oc}. In contrast, because charge carriers have a propensity to remain in trap states, the photoetch step may selectively etch surface defects, thereby offering a mechanism to increase V_{oc}. The trade-off between these two competing effects may account for the observation that photoetching improved V_{oc} in some cases and lowered it in others.

The nanorod arrays constantly exhibited better fill factors than typically obtained with planar systems. This observation is consistent with the slow interfacial electron-transfer kinetics of the S₂²⁻/S²⁻ electrolyte. These slow charge-transfer kinetics produce a competition for minority-carriers between collection across the interface and surface recombination, with the potential dependence of these processes determining the fill factor of the device. Accordingly, use of electron-transfer catalysts and/or rapid, one-electron transfer donors as redox species may improve the fill factor of n-GaAs/KOH(aq)-Se₂²⁻—Se²⁻ junctions. In such systems, increases in the surface area of the electrode can therefore tend to favor charge-transfer relative to surface recombination because, at constant light intensity, the minority-carrier flux to the junction is reduced as the internal junction area is increased. Hence, the observed increase in fill factor is a beneficial feature accompanying the use of nanorod array electrodes in such systems.

When a liquid junction contact is used in conjunction with a nanorod array electrode, a significant shunt conductance will be produced if the electrolyte directly contacts the back ohmic electrical contact. One way to mitigate this effect is by sputtering a thin layer of CdSe over the bottoms of the pores of the AAO at the beginning of the electrode fabrication process, as discussed above. In this way, the Ti contact cannot be exposed to the liquid electrolyte. However, there may be an issue as to whether the sputtered CdSe layer contributed significantly to the observed properties of the Cd(Se, Te) nanorod array photoelectrode. As indicated above, control experiments were conducted using this sputtered layer alone, and the resulting performance was quite low in comparison to what was measured for nanorod arrays. Considering that only a fraction of this area could be exposed to light when nanorods are present, the contribution of this sputtered CdSe layer to the overall performance is minimal. Such methods therefore demonstrate that it is possible to grow nanorod array electrodes in a template, without the use of a single crystal substrate of the material being grown to form the nanorod array, without significant shunting.

As discussed above, embodiments of the present invention may comprise nanorod arrays of Cd(Se, Te) fabricated using porous alumina templates to provide a photoelectrochemical cell. The discussed spectral response showed that the nanorod arrays acted as if they had longer diffusion lengths by facilitating the collection of charge-carriers generated with longer wavelength light. The ability of the nanorod arrays to maintain relatively high quantum yields in the red shows that this geometry provides improved carrier collection in diffusion limited systems. Furthermore, the nanorod arrays to have improved fill factors relative to their planar counterparts, which is likely attributable to better charge-transfer relative to surface recombination as a result of increasing internal junction area. Additional improvements in the performance of nanorod based solar cells may be obtained by lowering recombination at the junction. Using single crystal rods in the array may be one method by which this could be pursued.

The embodiments discussed above utilized the use of porous alumina templates and the deposition of Cd(Se, Te). However, as discussed above, alternative embodiments may use other methods for providing the templates for deposited semiconductor structures. In accordance with embodiments of the present invention, the deposited semiconductor structures again preferably orthogonalize the direction of light absorption with the direction of charge carrier collection. That is, the deposited semiconductor structures have length dimensions generally in the direction of the incident light and smaller width dimensions generally normal to the length dimensions. Hence, arrays of semiconductor structures with a variety of shapes, ordering, and density may be used.

### EXAMPLE 3

### Photoelectrochemical Cell Comprising Etched Semiconductor Structures

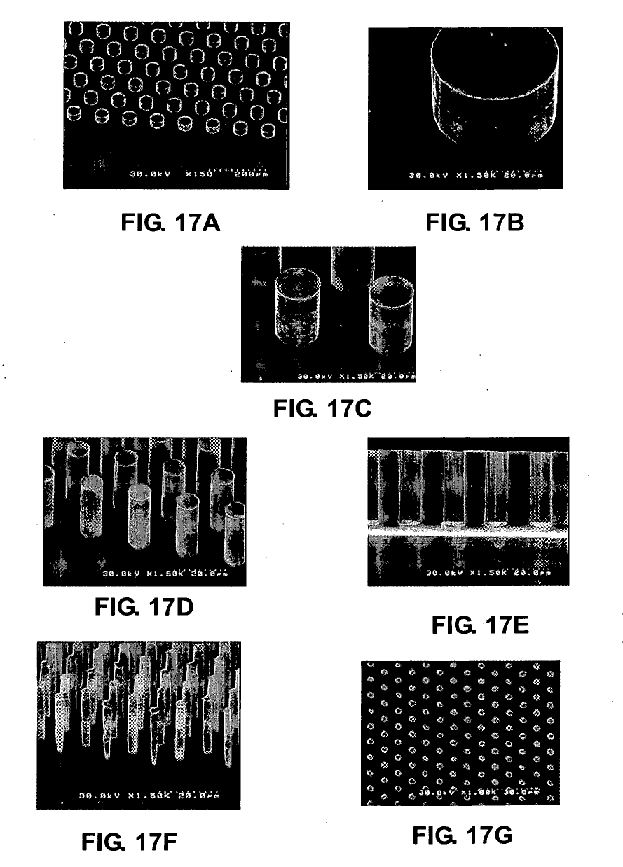

Another embodiment of the present invention comprises a photoelectrochemical cell having silicon pillars produced by etching a planar substrate. The silicon etched pillars may be fabricated using a low temperature Reactive Ion Etching (RIE) process. Such a process may be performed at nearly liquid nitrogen temperatures and can produce very deep etched structures. The planar substrate may be etched using photoresist as the masking medium. FIGS. 17A-17G show SEM images of pillars prepared by using an etch process. The photomask used to pattern the resist had areas containing arrays of 5, 10, 20, and 50 um diameter spots spaced in a hexagonal close packed array so that the same total filling fraction of pillars would result in each case. FIG. 17A shows an array of 50 μm diameter pillars and FIG. 17B shows a single 50 μm diameter pillar. FIG. 17C shows 20 μm diameter pillars. FIG. 17D shows 10 μm diameter pillars and FIG. 17E shows a side view of the 10 μm diameter pillars. FIG. 17F shows 5 μm diameter pillars and FIG. 17G shows a top down view of an array of 5 μm diameter pillars.

After the substrate was etched to prepare the pillars depicted in FIGS. 17A-17G, the substrate was subjected to a piranha etch following preparation, then oxidized to produce an oxide layer of about 50-100 nm. Buffered HF was used to remove the oxide layer. These steps were carried out to try to remove any surface impurities introduced during the RIE etching process. The substrate was then diced to produce samples with only one kind of pillar each, as well as samples having only the planar Si found in between pillar islands. The samples were made into electrodes and tested in a similar photoelectrochemical cell that to that depicted in FIG. 4. FIG. 18 shows representative current density versus voltage curves from the pillar samples using a liquid electrolyte similar to that used in Example 1 above. The curves shown were collected under approximately 1 sun of simulated solar illumination. Line 601 shows the results for a planar structure. Line 603 shows the results for the 50 μm pillars, line 605 shows the results for 20 μm pillars, line 607 shows the results for 10 μm pillars, and line 609 shows the results for 5 μm pillars.

The example discussed immediately above used RIE etching of a silicon substrate to provide semiconductor structures in accordance with embodiments of the present invention. However, other methods known to those skilled in the art may be used to fabricate the desired structures by removing material from a substrate or base layer. That is, other top-down methods may be used to fabricate the desired structures in addition to the bottom-up methods described and shown in examples 1 and 2.

### EXAMPLE 4

### Photoelectrochemical Cell for Production of Hydrogen

An embodiment of the present invention comprises an artificial photosynthetic system that utilizes sunlight and water as inputs and produces hydrogen and oxygen as the outputs. The system comprises the three distinct primary components: a photoanode, a photocathode, and a product-separating but ion-conducting membrane. These components may be fabricated and optimized separately before assembly into a complete water-splitting system. The system may incorporate two separate, photosensitive semiconductor/liquid junctions that collectively generate the 1.7-1.9 V at open circuit necessary to support both the oxidation of H₂O (or OH—) and the reduction of H⁺ (or H₂O).

The photoanode and photocathode may comprise arrays of semiconductor structures, as described above, and preferably comprise high aspect ratio structures such as rods or wires. The semiconductor structures within the arrays may have attached heterogeneous multi-electron transfer catalysts, which can be used to drive the oxidation or reduction reactions at low overpotentials. The high aspect-ratio semiconductor rod electrodes allow for the use of low cost, earth abundant materials without sacrificing energy conversion efficiency due to the orthogonalization of light absorption and charge-carrier collection. Additionally, the high surface-area design of the rod-based semiconductor array electrode inherently lowers the flux of charge carriers over the rod array surface relative to the projected geometric surface of the photoelectrode, thus lowering the photocurrent density at the solid/liquid junction and thereby relaxing the demands on the activity (and cost) of any electrocatalysts. A flexible composite polymer film may be used to allow for electron and ion conduction between the photoanode and photocathode while simultaneously preventing mixing of the gaseous products. That is, the rod arrays may be embedded in flexible, polymeric membrane materials, allowing the possibility of roll-to-roll system assembly. Separate polymeric materials may be used to make electrical contact between the anode and cathode, and also to provide structural support. Interspersed patches of an ion conducting polymer may be used to maintain charge balance between the two half-cells.

In a particular embodiment, the photocathode may comprise vertically (or near vertically) aligned rod arrays made of macroporous p-Si <100> with a resistivity of 13-15 Ω·cm. Preferably, the rod arrays are formed by etching the substrate (etched for 40 min in 10% KOH, and then electroetched under 50 mA for 2 hours in 1:2:3 HF:EtOH:H₂O) using a mask with 3 μm holes and a 7 μm pitch. Electrodes can be made using the rod arrays by using sputtered and annealed Al back contact connected to wire contact with silverprint. An electrochemical cell can be constructed using 1 M H₂SO₄ in 50% acetonitrile (to help with wetting pores), a Pt mesh counter electrode and Ag/AgCl reference electrode. When the cell is illuminated with light at λ=828 nm and with power levels of 0.002 to 100 mW/cm², the conversion of light energy to charge within the rods results in the release of hydrogen, i.e., the creation of fuel.

In another embodiment, the photoanode and photocathode components may be electrically, and ionically, interconnected through, but physically separated by, a flexible composite polymer film. Further, multi-component membranes, composed of polymeric materials, that exhibit desired mechanical pliability, electronic conductivity, and ion permeability properties for a feasible water electrolysis system my be used. Specifically, polypyrrole may be used to make electrical contact between the anode and cathode, while poly(dimethylsiloxane) (PDMS) may be used to provide structural support for the semiconductor rod arrays (in the manner as described above). For proton conduction in a cell operated under acidic conditions, Nafion may be employed, whereas vinylbenzyl chloride modified films of poly(ethylene-co-tetrafluoroethylene) (ETFE) may be used for hydroxide conduction in a cell operated under alkaline conditions.

Examples 1, 2 3, and 4 are not exhaustive of the devices and structures in accordance with embodiments of the present invention. As indicated, the semiconductor structures may have shapes other than the wire array, rod array, or pillar structures shown above. However, arrays of semiconductor structures are preferred, since such arrays provide the ability to increase the density of the light absorbing semiconductor structures. Well-order arrays provide an increased opportunity to increase the density. Conducting material may comprise material other than a liquid electrolyte. The structures may not be disposed on a substrate, but may have other material used to provide electrical contacts to one end of the structures or another. Further, as indicated in example 4, embodiments of the present invention are not limited to the production of electrical energy, but may also be used for fuel creation.

The examples described above are primarily directed to the use of embodiments of the present invention for solar energy conversion, i.e., solar cells. However, still other embodiments of the present invention having arrays of semiconductor structures as described above may find utility as capacitors and batteries in contact with liquids, conducting polymers or other such material, as well as supercapacitors. Still other embodiments of the present invention having arrays of semiconductor structures in radial contact with conducting material may also be used as sensors.

The foregoing Detailed Description of exemplary and preferred embodiments is presented for purposes of illustration and disclosure in accordance with the requirements of the law. It is not intended to be exhaustive nor to limit the invention to the precise form or forms described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom. This disclosure has been made with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising step(s) for . . . ”

What is claimed is:

1. A device comprising:
a base conducting layer;
an ordered array of elongate semiconductor structures, wherein the elongate semiconductor structures have length dimensions defined by adjacent ends in electrical contact with at least portions of the base conducting layer and distal ends not in contact with the base conducting layer and have radial dimensions generally normal to the length dimensions and the radial dimensions are less than the length dimensions; and
a charge conducting layer, wherein at least some portions of the charge conducting layer are in electrical contact with one or more elongate semiconductor structures of the plurality of the elongate semiconductor structures along at least portions of the length dimensions of the one or more elongate semiconductor structures,
wherein the elongate semiconductor structures absorb received light.

2. The device according to claim 1, wherein the radial dimensions are less than or equal to minority carrier diffusion lengths for material comprising the elongate semiconductor structures.

3. The device according to claim 2, wherein ratios of the radial dimensions to the length dimensions are optimal or near optimal for conversion of solar energy to electricity.

4. The device according to claim 1, wherein the base conducting layer comprises a substrate and the elongate semiconductor structures comprise structures grown from the substrate.

5. The device according to claim 1, wherein the base conducting layer comprises a substrate and the elongate semiconductor structures comprise structures deposited on the substrate.

6. The device according to claim 1, wherein the base conducting layer comprises a substrate and the elongate semiconductor structures comprise structures resulting from etching the substrate.

7. The device according to claim 1, wherein the charge conducting layer comprises a liquid electrolyte.

8. The device according to claim 1, wherein the charge conducting layer comprises at least one or more of the following elements: a conducting polymer; a metal oxide semiconductor interface; and a PN junction.

9. The device according to claim 1, wherein the elongate semiconductor structures comprise arrays of semiconductor structures having at least one or more of the following shapes: rods, pyramids, and trees.

10. The device according to claim 1, wherein the elongate semiconductor structures comprise semiconductor structures conformably embedded in the charge conducting layer along at least a portion of the length dimensions of the elongate semiconductor structures.

11. A photocell comprising:
a substrate;
one or more wire arrays comprising a plurality of oriented and ordered semiconductor wires, wherein the plurality of semiconductor wires have adjacent ends contiguous with the substrate and distal ends oriented to receive incident light, wherein the adjacent ends and distal ends define a length dimension for each semiconductor wire and wherein each semiconductor wire has a radius less than or equal to minority carrier diffusion lengths for material comprising the semiconductor wire; and
a charge conducting layer, wherein at least some portions of the charge conducting layer are in electrical contact with one or more semiconductor wires along at least portions of the length dimensions of the one or more semiconductor wires,
wherein the semiconductor wires absorb received light and whereby a ratio of the length dimension to the radius for each semiconductor wire is optimal or near optimal for solar energy conversion for materials comprising the one or more semiconductor wires.

12. The photocell according to claim 11, wherein the semiconductor wires in the one or more wire arrays comprise at least one of the following semiconductor wires: semiconductor wires grown from the substrate; semiconductor wires deposited on the substrate; and semiconductor wires formed by etching the substrate.

13. The photocell according to claim 11, wherein the charge conducting layer comprises at least one of the following materials: a non-aqueous solvent with an electrolyte; an aqueous solvent with an electrolyte; a conducting polymer, semiconductor material, and metal.

14. The photocell according to claim 11, wherein the semiconductor wires comprise at least one of the following materials: crystalline silicon; amorphous silicon; micromorphous silicon; protocrystalline silicon; nanocrystalline silicon; cadmium telluride; copper-indium selenide; copper indium gallium selenide gallium arsenide; gallium arsenide phosphide; cadmium selenide; indium phosphide; a-Si:H alloy, and combinations thereof.

15. The photocell according to claim 11, wherein the one or more wire arrays comprise semiconductor wires uniformly or nearly uniformly spaced apart, wherein spacings between the semiconductor wires are selected to maximize light energy conversion by the photocell.

16. A photocell for conversion of water to hydrogen comprising:
a photoanode comprising one or more ordered wire arrays comprising a plurality of elongate photoanode semiconductor wires, wherein the photoanode semiconductor wires are oriented to receive incident light;
a photocathode comprising one or more ordered wire arrays comprising a plurality of elongate photocathode semiconductor wires, wherein the photocathode semiconductor wires are oriented to receive incident light; and
a film electrically and ionically interconnecting the a plurality of the photoanode semiconductor wires to a plurality of the photocathode wires.

17. The photocell according to claim 16, wherein the film comprises a flexible composite polymer film.

18. The photocell according to claim 16, wherein the film prevents mixing of gaseous products.

19. The photocell according to claim 16, wherein photoanode semiconductor wires and/or the photocathode semiconductor wires have attached heterogeneous multi-electron catalysts.

20. The photocell according to claim 16, further comprising interspersed patches of an ion conducting polymer.
